(19) United States
(12) Patent Application Publication
(10) Pub. No.: US 2005/0218983 A1
(43) Pub. Date: Oct. 6, 2005

(54) Differential amplifier

(75) Inventors: Akiyoshi Matsuda, Kasugai (JP); Tsunehiko Moriuchi, Kasugai (JP); Hiroko Haraguchi, Kasugai (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/094,362

(22) Filed: Mar. 31, 2005

Related U.S. Application Data
(63) Continuation-in-part of application No. 10/943,975, filed on Sep. 20, 2004, now abandoned.

(30) Foreign Application Priority Data
Apr. 2, 2004 (JP) 2004-110204
Jan. 31, 2005 (JP) 2005-023986

(51) Int. Cl. H03F 3/45

(52) U.S. Cl. 330/257

(57) ABSTRACT

The differential amplifier of the present invention has a current source connected between a grounding wire and a terminal which can be the output point of the differential amplifier among the terminals of each transistor which constitutes the differential amplifier and to which one of two inputs to the differential amplifier is given, or a circuit element connected between the terminals which can be the output points of the differential amplifier, or two transistors which are connected to each of the terminals which can be the output points of the differential amplifier and one of which turns off when the other is on, and one of which turns on when the other is off, and the current source is connected between the two transistors and the grounding wire.

### CROSS-REFERENCE TO RELATED APPLICATIONS

This patent application is a continuation in part application of the previous U.S. patent application, titled “DIFFERENTIAL AMPLIFIER”, filed on Sep. 20, 2004, application Ser. No. 10/943,975, herein incorporated by reference.

### BACKGROUND OF THE INVENTION

1. Field of the Invention

The present invention relates to a semiconductor device, and more specifically to a differential amplifier having a current mirror circuit which delivers an output to the side of a load by an electric current, for example, a high-speed operation system of a differential amplifier used as a high-speed data transfer driver.

2. Description of the Related Art

A differential amplifier is used in a wide range of fields. FIG. 1 shows a general configuration of such a differential amplifier. This differential amplifier is a combination of a differential pair with a diode-connected load and a source follower circuit, and a current mirror circuit is constituted by said combination, and the output of the differential amplifier is delivered to the side of the load by an electric current.

The differential pair and source follower circuit which constitutes the differential amplifier are described in the following documents.

Non-patent document 1: “Design of Analog CMOS Integrated Circuits,” Basic Edition, page 83, written by B. Razavi, translated by Tadahiro Kuroda, published by Maruzen

Non-patent document 2: “Design of Analog CMOS Integrated Circuits,” Applications Edition, page 394, written by B. Razavi, translated by Tadahiro Kuroda, published by Maruzen

In FIG. 1, a transistor 100 and a transistor 101 to which a non-inverting input and an inverting input are supplied respectively are connected to a grounding wire by a power source 102, and are connected to a source voltage VDD by transistors 103 and 105. Diode-connected transistors 103 and 105, transistor 104, transistor 106 constitute a current mirror circuit, and the transistor 104 and the transistor 106 to which a copy electric current flows in the current mirror circuit are connected to resistors 107 and 108 on the side of the load respectively, and the voltage applied to the resistors 107 and 108 is taken out as an output voltage.

In FIG. 1, when either an input signal VIN+ or an input signal VIN− becomes H, the voltage of a node 1 or a node 2 begins to drop from the source voltage VDD. When the electric potential of the node 1 or the node 2 becomes lower than the value obtained by subtracting a threshold voltage from the source voltage, an electric current begins to flow to the transistor 103 and the transistor 105, and this electric current flows to the side of the output resistor by the current mirror circuit, and an output voltage is generated.

However, in the circuit shown in FIG. 1, a delay time exists from the time when an input signal is on, or H to the time when an electric current flows to the transistor 103 or 105. FIG. 2 is an explanatory drawing of this delay time. In FIG. 2, when an input signal is on, or H, the voltage of the node 1 or the node 2 begins to drop, but an electric current does not flow to the transistor 103 or the transistor 105 until the value of the voltage becomes equal to or lower than the value obtained by subtracting the threshold voltage from the source voltage. Consequently, the time when the rising of the electric current on the copy side of the current mirror starts, i.e. the time when the rising of the current which flows to the transistor 104 or the transistor 106, starts is accordingly delayed, and the output voltage delayed by the same amount.

When a differential amplifier is used as a driver circuit for high-speed data transfer, this delay time becomes a serious problem. Particularly, in order to realize the transfer speed of 480 Mbps as set forth in the USB (Universal Serial Bus) 2.0 Standard, a delay time of 100 ps or so becomes a problem. Furthermore, in order to satisfy the stress test standard of USB 2.0, there is a problem in that it is difficult to use a low withholding voltage and high-speed transistor, and it is necessary to make a large electric current flow, so the size of the transistor becomes large, and the load capacity becomes large, and the delay time also becomes long.

The following documents are available as prior art concerning such a differential amplifier.

Patent document 1: Kokai (Jpn. unexamined patent publication) No. 10-209844 “Small level signal input interface circuit”

Patent document 2: Kokai (Jpn. unexamined patent publication) No. 11-127042 “Differential amplifier”

Disclosed in patent document 1 is an interface circuit which improves the operation speed in an ordinary operation mode other than the IDDQ test mode which is a test method of a semiconductor integrated circuit, which reduces the number of clocked inverters in order to reduce the circuit area, and which improves the performance.

Disclosed in patent document 2 is a differential amplifier which can reduce an average consumption of electric current within a range of the whole current input by making the output electric current variable according to the level of a non-inverting input voltage.

However, the aforesaid prior art could not solve the problem in that in a differential amplifier having a current mirror circuit shown in FIG. 1, the transistor constituting the current mirror circuit is cut off when the corresponding input voltage is L, and a delay arises in the operation.

### SUMMARY OF THE INVENTION

The purpose of the present invention is to realize an increase of the operation speed of a differential amplifier by preventing the transistors constituting a current mirror circuit from being cut off even when the corresponding input voltage is L.

A first differential amplifier of the present invention has a current source connected between a grounding wire and the terminal which can be the output point of the differential amplifier among the terminals of each transistor which constitutes the differential amplifier and to which one of two inputs to the differential amplifier is given.

A second differential amplifier of the present invention has a circuit element connected between the terminals which can be the output points of the differential amplifier among the terminals of each transistor which constitutes the differential amplifier and to which one of two inputs to the differential amplifier is given.

A third differential amplifier of the present invention has two transistors which constitute the differential amplifier and are connected to the terminals which can be the output points for the differential amplifier among the terminals of each transistor to which one of the two inputs for the differential amplifier is given, and one of which turns off when the other is on, and one of which turns on when the other is off, and where the current source is connected between the two transistors and the grounding wires.

A fourth differential amplifier of the present invention has transistors which constitute the differential amplifier and to which one of two inputs to the differential amplifier is supplied, and a cut-off prevention device which is connected to the connecting point of the transistors to which a monitor current of the current mirror circuit flows to deliver the output of the differential amplifier to the side of the load and which makes the current which does not cut off the transistors to which the monitor current flows flow even when the input to the transistors to which the input is given is L.

### BRIEF DESCRIPTION OF THE DRAWINGS

FIG. 1 shows a conventional configuration of a differential amplifier.

FIG. 2 shows an explanatory drawing of current delay in the conventional configuration shown in FIG. 1.

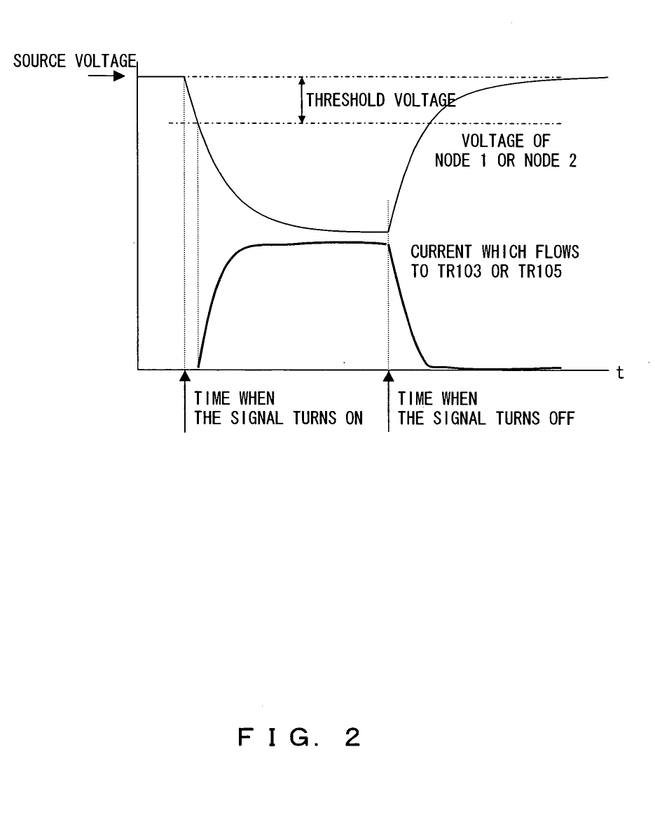

FIG. 3 shows a configuration indicating the principle configuration of the differential amplifier of the present invention.

FIG. 4 shows an example of the image data transfer system in which the differential amplifier of the present invention is used.

FIG. 5 shows a configuration of the LSI in a digital camera shown in FIG. 4.

FIG. 6 shows a basic configuration of the differential amplifier of the present invention.

FIG. 7 shows a waveform of the current which flows to the transistors constituting the differential amplifier show in FIG. 6.

FIG. 8 is a time chart showing the relationship between an input signal and an output signal in the differential amplifier of the present invention.

FIG. 9 shows a configuration of a first embodiment of the differential amplifier.

FIG. 10 shows the configuration of a second embodiment of the differential amplifier.

FIG. 11 explains an example of a current value when a bias voltage is determined in the first and the second embodiments.

FIG. 12 is an explanatory drawing of a method of determining a bias voltage biasp.

FIG. 13 is an explanatory drawing of the method of determining the size of a transistor.

FIG. 14 shows a configuration of a third embodiment of the differential amplifier.

FIG. 15 shows a configuration of the fourth embodiment of the differential amplifier.

FIG. 16 shows a configuration of a fifth embodiment of the differential amplifier.

FIG. 17 shows the leakage current due to process fluctuations.

FIG. 18 shows the configuration of a sixth embodiment of the differential amplifier.

FIG. 19 shows the configuration of a seventh embodiment of the differential amplifier.

FIG. 20 shows the configuration of an eighth embodiment of the differential amplifier.

### DESCRIPTION OF THE PREFERRED EMBODIMENTS

Described below are details of the preferred embodiments of the present invention with reference to the accompanying drawings.

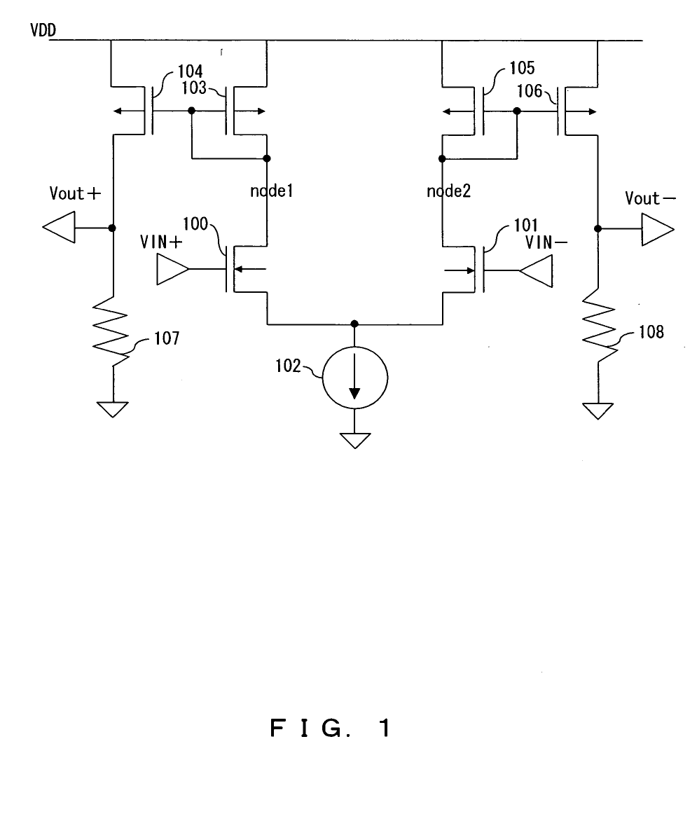

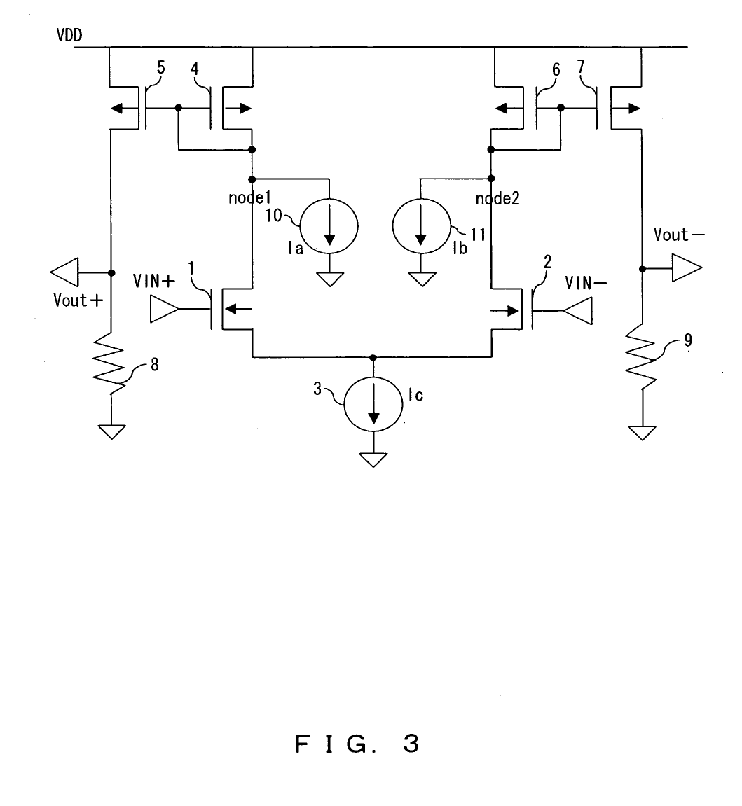

FIG. 3 shows a configuration indicating the principle of the differential amplifier of the present invention. The same figure shows the configuration indicating the principle of the present invention in comparison with the conventional configuration shown in FIG. 1. As compared with the conventional configuration shown in FIG. 1, the configuration of the differential amplifier of the present invention basically differs in that current sources 10 and 11 are connected between a node 1 and a node 2 and grounding wires.

In other words, in the differential amplifier of the present invention, the current sources 10 and 11 are provided between the terminals of the transistors which can be the output of the differential amplifier, i.e., the node 1 and the node 2 and the grounding wires, inside of the terminals of the transistors which constitute the differential amplifier and to which one of two inputs is given.

The functionally described below is the principle of the present invention. The differential amplifier of the present invention has a cut-off prevention means which is connected between the connection point of the above-recited transistor to which one of two inputs is supplied and that of the transistor to which the monitor current of the current mirror circuit flows to deliver the output of the differential amplifier to the side of the load and which makes the current which does not cut off the transistor to which the monitor current flows flow, even when the input, which corresponds to the transistor to which the input is given and the current mirror circuit, is L.

This cut-off prevention means can be a current source connected between the transistor to which the input is supplied and the grounding wire, and can be a circuit element connected between the connection point of the transistor to which the input is supplied and that of the transistor to which the monitor current flows, and further, the circuit element can be a transistor in which a small current flows, or a resistor.

In an embodiment of the present invention, a first transistor to which a copy current flows in the current mirror circuit, and a second transistor which is connected to the resistor as a load to which the output of the differential amplifier is delivered and which turns off when the input to the above-recited transistor, to which one of two inputs is given, is L, and further a current source which is connected between the connection point of the first transistor and the second transistor and the grounding wires can be provided.

The current source connected to the connection point of the first and the second transistors and the current source connected to the node 1 and the node 2 are constituted by transistors, and the transistors and the bias circuit units which apply bias voltages to the transistors can constitute the current mirror circuit.

Moreover, the transistors of one or more stages to which a bias voltage applied by the bias circuit unit and the transistors of two stages which are connected between the transistors of one or more stages and the source voltage and which applies a bias voltage for turning off the second transistor when the input is L can be provided as the circuit which applies a bias voltage to the second transistor.

Moreover, the gate of the transistor of two stages is connected to the connection point of the transistor of one or more stages and the two-stage transistors, and the bias voltage which is supplied to the second transistor can be determined by adjusting the size of the two-stage transistors and the current which flows to the transistors.

In the embodiment of the present invention, the current mirror circuit having the current source, etc., connected between the first transistor and the second transistor and a bias circuit unit which applies a bias voltage to the transistor constituting the current source can be constituted by a cascade current mirror circuit in which the output resistance of the current source is large, a transformed cascade current mirror circuit in which the lowest limit of the output voltage of the current source is low, and a low-voltage mirror circuit which cascade-connects the transistor to which a copy current flows and the transistor to which a reference current flows using two reference currents.

In another embodiment of the present invention, a third transistor which is connected to the connecting point of the first transistor and the second transistor and turns on when the input to the transistor to which either of the aforesaid two inputs is supplied is L in addition to the first transistor and the second transistor in the current mirror circuit as well as the current source connected between the third transistor and the grounding wire can be also provided, and in this case, a fourth transistor which is connected between the source voltage and the current source connected between the third transistor and the grounding wire and which turns on when the input of the transistor to which either of the aforesaid two inputs is supplied is H can be also provided.

The differential amplifier of the present invention is provided with two transistors which constitute the differential amplifier and are connected to each terminal which can be the output point for the differential amplifier among the terminals of each transistor to which either of the two inputs for the differential amplifier is given, and one of which turns off when the other is on, and one of which turns on when the other is off, as well as the current source connected between the two transistors and the grounding wires.

This differential amplifier can be also provided with two current mirror circuits which deliver the output of the differential amplifier to the load side by means of an electric current, the first transistor in which each transistor to which one of the inputs is given is connected to the transistor in which a monitor current flows in each current mirror circuit, and a copy current flows in the current mirror circuit, the second transistor which is connected to the resistor as the load to which the output is delivered and which turns off when the input to the transistor to which either of the two inputs is given is L, the third and fourth transistors which are connected to the connecting point of the first transistor and the second transistor in each current mirror circuit and one of which turns off when the other is on and one of which turns on when the other is off in accordance with the input value of the differential amplifier, and the current source connected between the third and fourth transistors and the grounding wires.

Thus, according to the present invention, the differential amplifier can be made to operate without cutting off the transistor which constitutes the current mirror circuit and in which a monitor current flows even when the input to the corresponding transistor is L by connecting the current source to the connecting point of the transistors to which inputs to the differential amplifier are supplied and the current mirror circuit which delivers outputs to the load.

According to the present invention, the differential amplifier which is provided with a current mirror circuit which delivers outputs, for example, to the load side by means of an electric current can be made to operate at high speed without cutting off the transistor to which a monitor current flows in the current mirror circuit even when the input voltage is L.

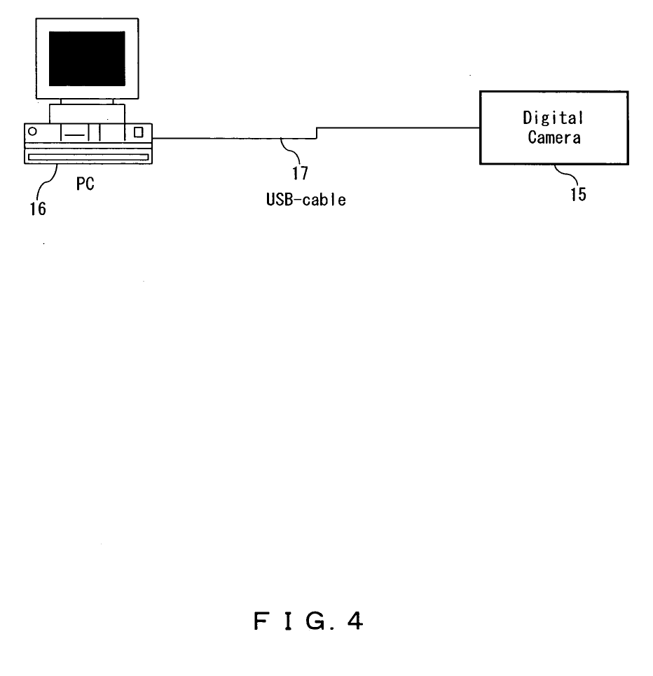

The differential amplifier embodying the present invention is used for a data transfer driver circuit when data transfer using, for example, a USB cable is implemented. FIG. 4 is a block diagram of a connecting system of a digital camera and a personal computer using such a USB cable. In FIG. 4, the digital camera 15 and the personal computer 16 are connected by the USB cable 17, and image data, for example, is transferred from the digital camera 15 to the personal computer 16 by the USB cable 17. This driver circuit for transferring this image data is provided inside of the digital camera 15, and the differential amplifier is used as that driver circuit.

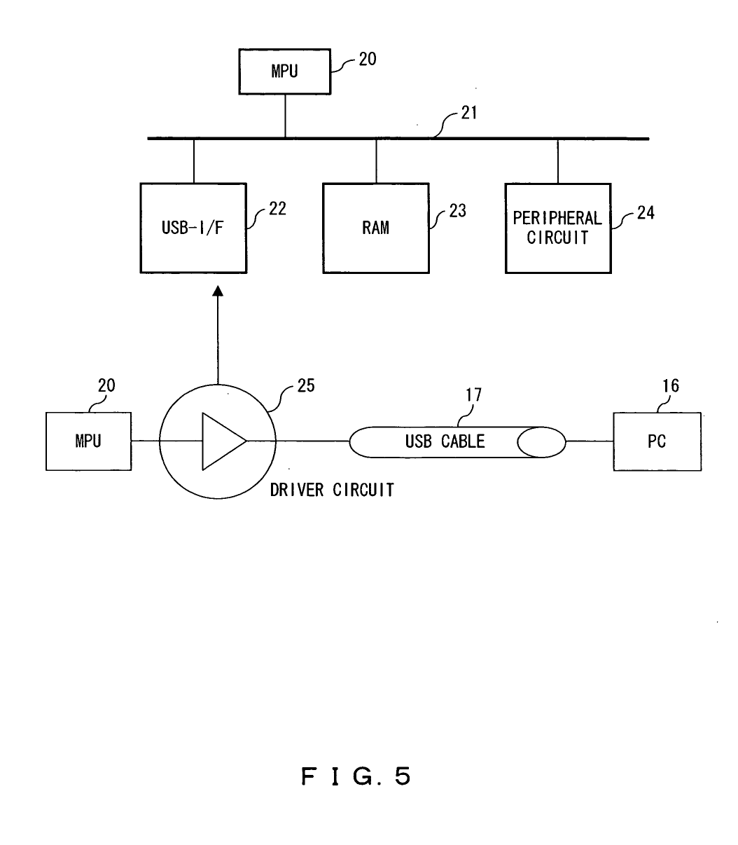

FIG. 5 is an explanatory drawing of the LSI configuration in the digital camera shown in FIG. 4 and the data transfer method. In FIG. 5, the LSI in the digital camera comprises a microprocessor (MPU) 20 controlling the whole of the digital camera, a bus 21, a USB interface 22, random access memory 23, and a peripheral circuit 24.

A driver circuit 25 constituted by the differential amplifier embodying the present invention is a part of the USB interface 22, and transmits, for example, image data to the personal computer 16 via the USB cable 17 under the control of the MPU 20.

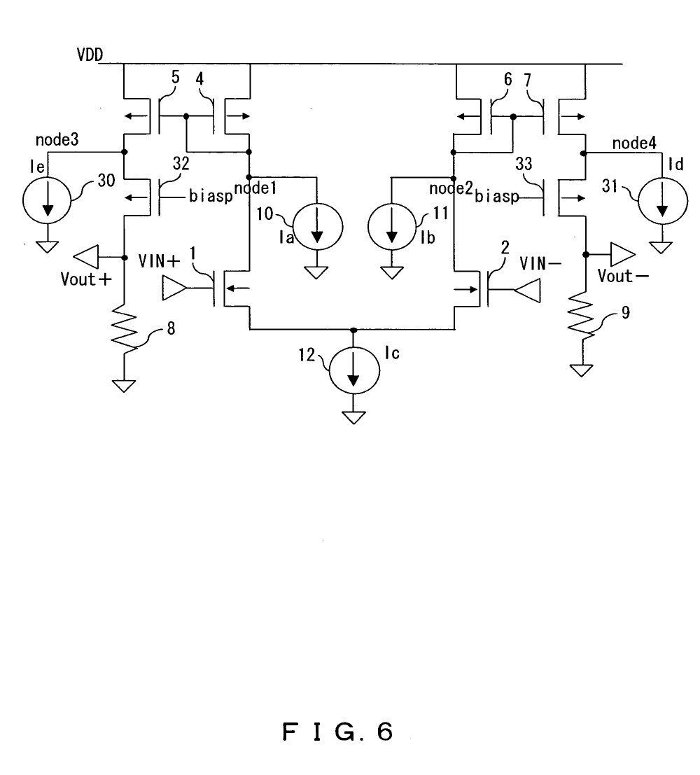

FIG. 6 shows the basic configuration of the differential amplifier of the present invention. When the basic configuration shown in FIG. 6 is compared with the principle configuration of the differential amplifier shown in FIG. 3, it is found to different in that transistors 32 and 33 are connected to the transistors 5 and 7 respectively, in which the current copied in the current mirror circuit shown in FIG. 3 flows and the resistors 8 and 9; and that Ie30 is connected to the connection point of the transistor 5 and the transistor 32, i.e., a node 3, and that a current source Id31 is connected at the connection point of the transistor 7 and the transistor 33, i.e., a node 4. Resistors 8 and 9 play the role of terminal resistors on the data transfer side in the driver circuit shown in FIG. 6. The transistor 5 or 7 shown in FIG. 6 corresponds to the first transistor in claim 3 of the present invention, and the transistor 32 or 33 corresponds to the second transistor.

In the principle configuration principle shown in FIG. 3, a weak current is made to always flow to the transistor 4 and the transistor 6 even when the input is L by connecting current sources Ia10 and Ib11 to the node 1 and the node 2, respectively and so that these transistors will not be cut off. However, since this weak current is flowing to the transistor 4 or the transistor 6, an electric current also flows to the transistors to which the current copied in the current mirror circuit flows, i.e., the transistor 5 and the transistor 7, thus causing an output voltage to be generated.

Thereupon, an electric current which flows to the transistor 5 and the transistor 7 is made to flow to the side of the current source by connecting current sources Ie30 and Id31 to a node 3 and a node 4 respectively, and not to flow to the terminal resistor 8 or 9, as shown in the basic configuration shown in FIG. 6. Even though an electric current is made to flow to the side of the current source, the voltage of the node 3 and the node 4 do not become 0 completely, an output voltage is generated. The output voltage can be made 0 by inserting transistors 32 and 33 and turning these transistors off in the state in which the input of the gate voltage bisap is L, that is, adjusting the gate voltage so that the electric potential drops from the electric potential of the node 3 or the node 4 by that of the threshold voltage. Then, in the state in which the input voltage becomes H, and a comparatively large current flows to the transistor 5 or the transistor 6, the electric potential of the node 3 and the node 4 rises, and Vgs in a transistor 32 or a transistor 33 becomes large, and an electric current flows to the terminal resistor 8 or 9.

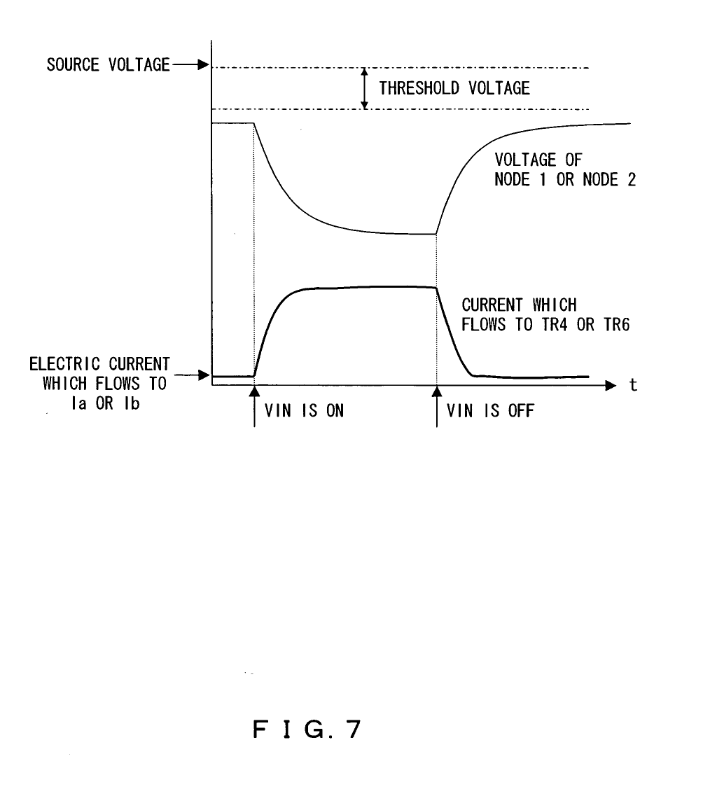

FIG. 7 shows the change of an electric current, for example, in the basic configuration shown in FIG. 6. Before an input voltage VIN turns on, the transistor 4 or the transistor 6 is not cut off even if the current which flows to the current source Ia10 or Ib11 is weak. When VIN signal turns on, the voltage of the node 1 or the node 2 drops, and the current which flows to the transistor 4 or the transistor 6 increases. The voltage of the node 1 or the node 2 is kept lower than the source voltage by a value which is equal to or higher than a threshold voltage.

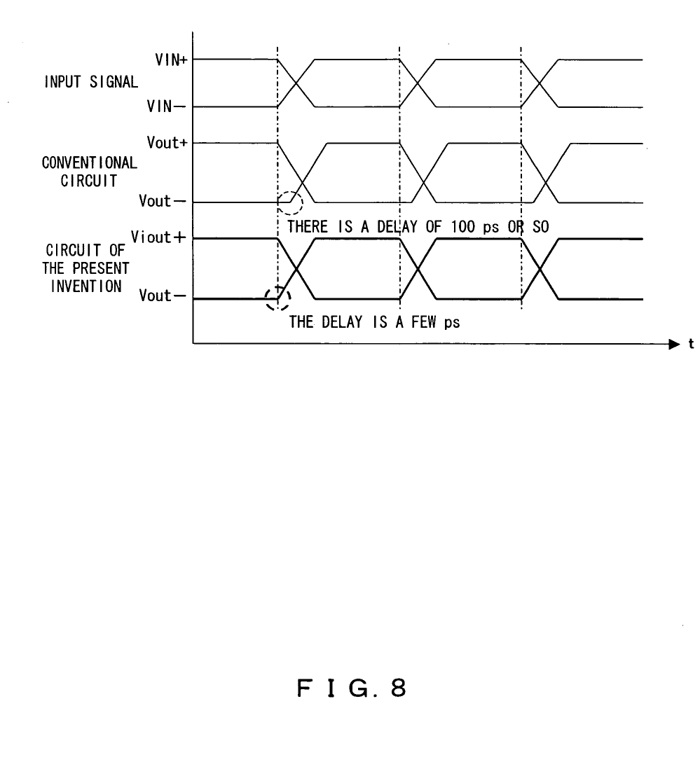

FIG. 8 is a time chart of an input signal and an output signal which correspond to the basic circuit shown in FIG. 6. Compared with the uppermost input signal shown in FIG. 8, a delay of 100 ps or so arises from the time when an input signal begins to boot up to the time when an output signal begins to boot up in the conventional circuit as shown in FIG. 1. In the circuit of the present invention, the delay is only a few ps, so that problems such as lags of a cross point and differences of duty ratio, etc., as in the conventional circuit can be solved.

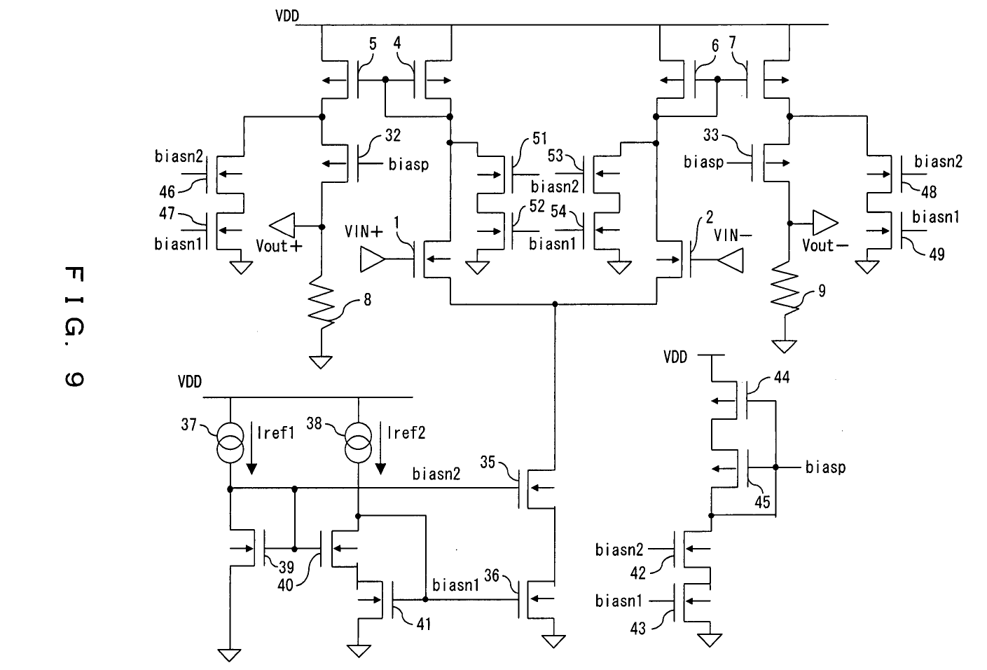

FIG. 9 shows the configuration of the first embodiment of the differential amplifier of the present invention. In this first embodiment, in which a mutual conductance and output resistor as basic physical parameters of a MOSFET can be easily represented using a current I, a current bias circuit is used as a bias circuit, and in order to mirror the current accurately in the current mirror circuit, the bias circuit is configured as a cascade type, and a low-voltage current mirror circuit which can decrease the lowest limit of the output voltage of the current source circuit is used.

This low-voltage current mirror circuit comprises two reference current sources 37 and 38 which determine bias voltages biasn1 and biasn2, three transistors 39, 40 and 41, and these bias voltages are applied to the gates of two transistors 35 and 36, and the current source Ic12 shown in FIG. 6 is constituted as a whole.

The four current sources shown in FIG. 6 comprises two transistors in which two bias voltages are applied to the gates respectively. The current source Ia10 comprises transistors 51 and 52; the current source Ib11 comprises transistors 53 and 54, the current source Ie30 comprises transistors 46 and 47; and the current source Id 31 comprise transistors 48 and 49.

The bias voltage biasp which is applied to the gates of the transistor 32 and the transistor 33 is determined so that the transistor 32 or the transistor 33 turns off when the input voltage is L by connecting the transistor 42 and the transistor 43 in which two bias voltages biasn1 and biasn2 are applied to the gates respectively, as shown in the right bottom of FIG. 9, and further by using two transistors 44 and 45 in the path to the VDD. This determination will be further described later.

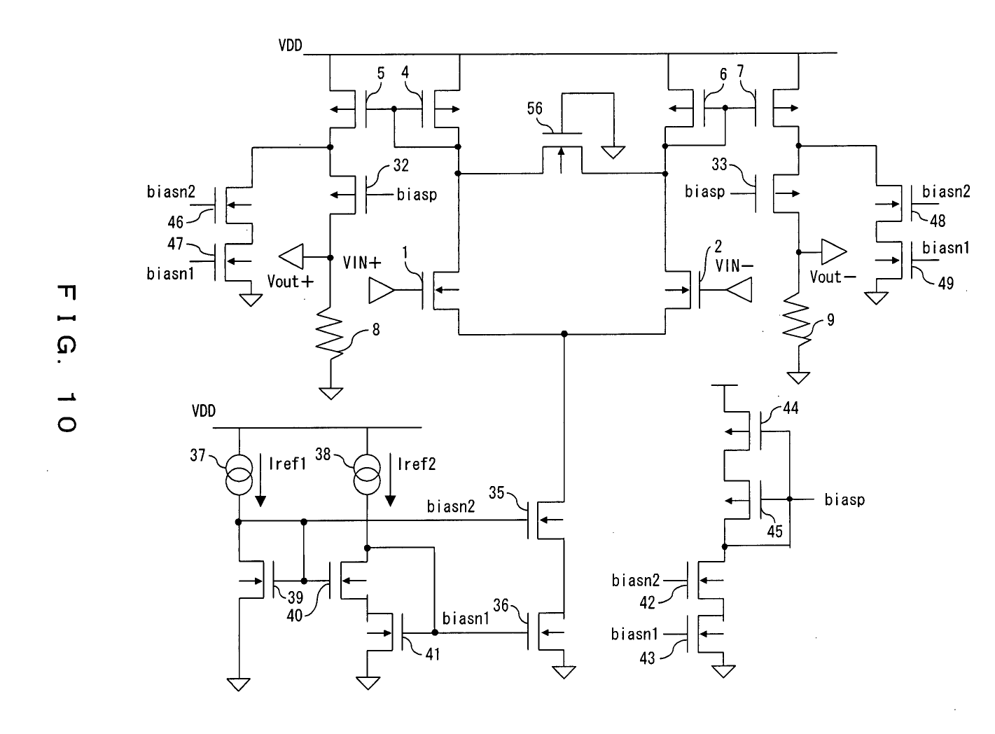

FIG. 10 shows the configuration of the second embodiment of the differential amplifier. When the configuration of FIG. 10 is compared with the configuration of the first embodiment shown in FIG. 9, it is found to be different in that a transistor 56 which connects the two output points of the differential amplifier is provided in place of transistors 51 and 52 and the transistors 53 and 54 which constitute two current sources Ia10 and Ib11 respectively as shown in FIG. 9. In FIG. 10, for example, when input voltage VIN+ to the gate of the transistor 1 is H, a weak current flows to the transistor 6 via the transistor 56. Consequently, the transistor 6 which was cut off in the conventional circuit is not cut off, and a high-speed response can be possible in the same way as in the first embodiment shown in FIG. 9. This transistor 56 can be an element which can make a weak current flow, and it can be substituted by, for example, a resistor.

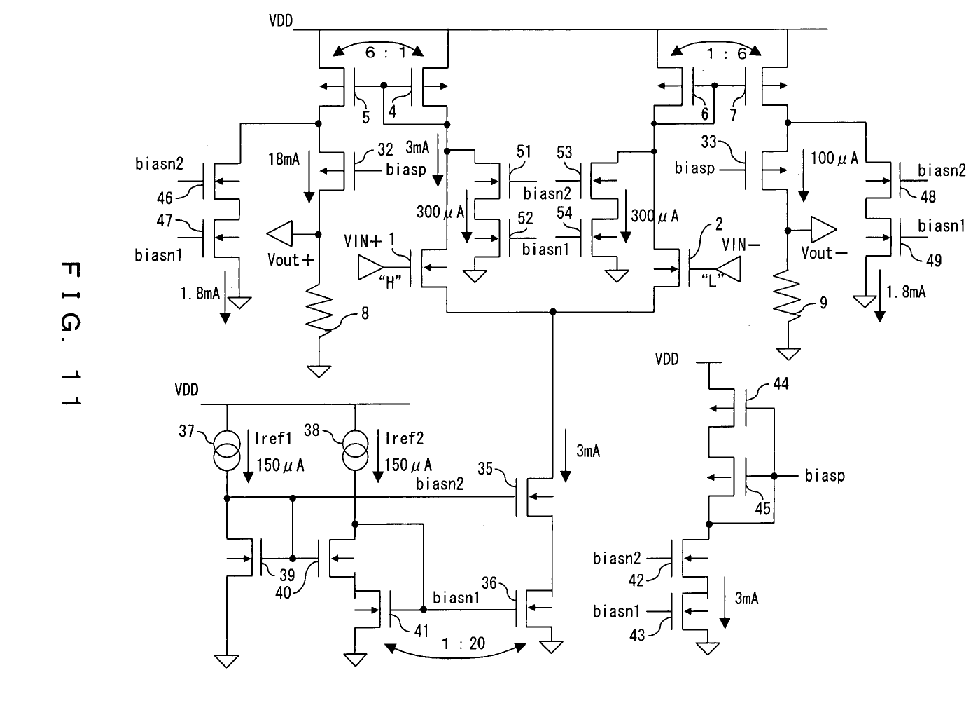

Further described below is the determination of a bias voltage in these two embodiments with reference to FIGS. 11 to 13. FIG. 11 shows an explanatory drawing of with specific current values in the circuit when the bias voltage biasp is determined in the first embodiment shown in FIG. 9. In the first embodiment shown in FIG. 9, for example, the value of the bias voltage biasp is determined by adjusting the size of the two-stage connected p-channel transistors 44 and 45 and the current which flows therein. FIG. 11 is an explanatory drawing of this adjustment and the current values and voltage values when the transistor size of the transistors 32 and 33 in which the bias voltage is applied to the gates is determined.

If the current which flows to the transistor 6 is set to 300 μA when the input voltage VIN− to the gate of the transistor 2 is L, the current of 1.8 mA which is six times as much as 300 μA flows to the transistor 7 in accordance with the size ratio of the transistor in the current mirror circuit. This current basically flows towards the current source Id, i.e., the transistors 48 and 49.

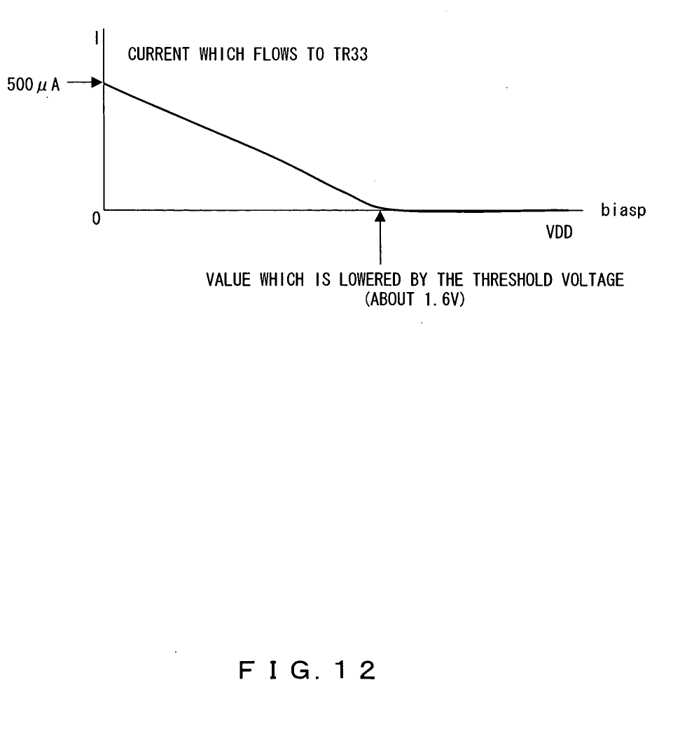

At that time, if the electric potential of the connection point of the transistors 7 and 33, i.e. the position of the node 4 is set to 2.2 V, an electric current begins to flow to the transistor 33 when the electric potential of biasp is lowered by the value of the threshold voltage (about 0.6 V). FIG. 12 is an explanatory drawing of the relationship between this current and the value of biasp. Since it is difficult to determine the value of biasp accurately when the current of Tr33 begins to actually flow, the value of biasp provided when the current becomes 100 μA is obtained by an estimate from FIG. 12 in the preferred embodiment of the present invention.

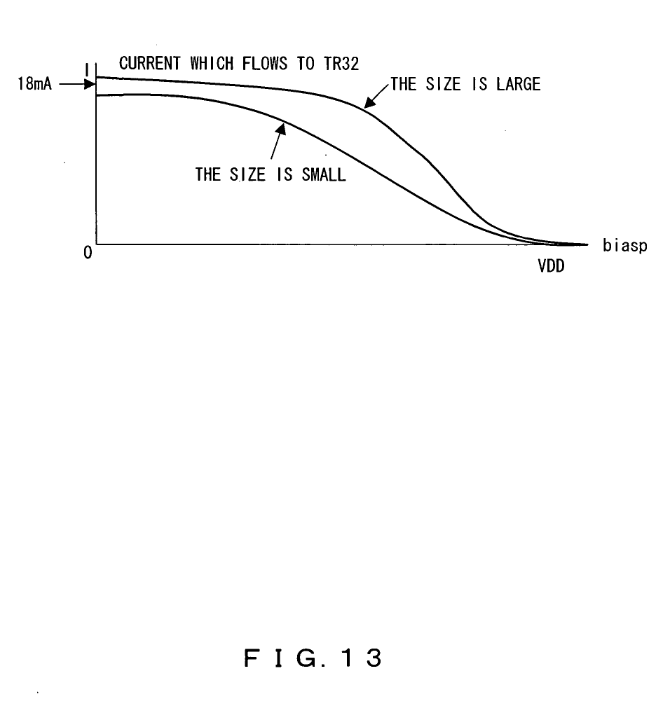

Even if the electric potential of the connection point of the transistors 5 and 32, i.e., the node 3 is high, and the value of biasp is close to VDD, an electric current flows to the transistor 32. Then, the size of the transistor 32 is determined in such a way that a desired current (here, 18 mA) flows when the value of biasp is the estimated value, as shown in FIG. 13.

Next, described below is the determination of bias voltages biasn1 and biasn2 which are applied to the gates of two transistors, for example, 35 and 36 constituting each current source shown in FIG. 9. For example, the biasn1 applied to the gate of the transistor 36 is determined by the following expression using the size of the transistor 41, the value of a current Iref2 which flows therein, a threshold voltage Vr, and the parameter β₁ which is proportional to the channel width and channel length of the transistor 41.
biasn1=Vᵣ+\sqrt{2Iref2/β₁} [Expression 1]

Next, the gate voltage biasn2 of the transistor 35 is determined by the following expression using the size of the transistor 39, the parameter β₂ and the current Iref1.
biasn2=Vᵣ+\sqrt{2Iref1/β₂} [Expression 2]

In the low-voltage current mirror circuit, the value of the bias voltage biasn2 is determined by the following expression by making the values of two reference voltages equal (Iref1=Iref2) and making the size ratio of the transistor 41 and the transistor 39 4 to 1.
biasn2=Vᵣ+\sqrt{2Iref2/0.25β₁}=Vᵣ+2\sqrt{2Iref2/β₁} [Expression 3]

It is explained in the first and the second embodiments shown in FIG. 9 and FIG. 10 that the accuracy of the current mirror can be improved by using a low-voltage current mirror circuit, and that the voltage value range in which a CMOS analog circuit can be used by lowering an output voltage can be expanded. However, in the differential amplifier of the present invention, various kinds of current mirror circuits can be used without being limited to such a low-voltage current mirror circuit. Details of the various kinds of low-voltage current mirror circuits including a low-voltage current mirror circuit are described in the following document.

Non-patent document: “A Guide to CMOS Analog Circuit—Bias Circuit” in Design Wave Magazine 2002, August, Page 153, by Kenji Taniguchi

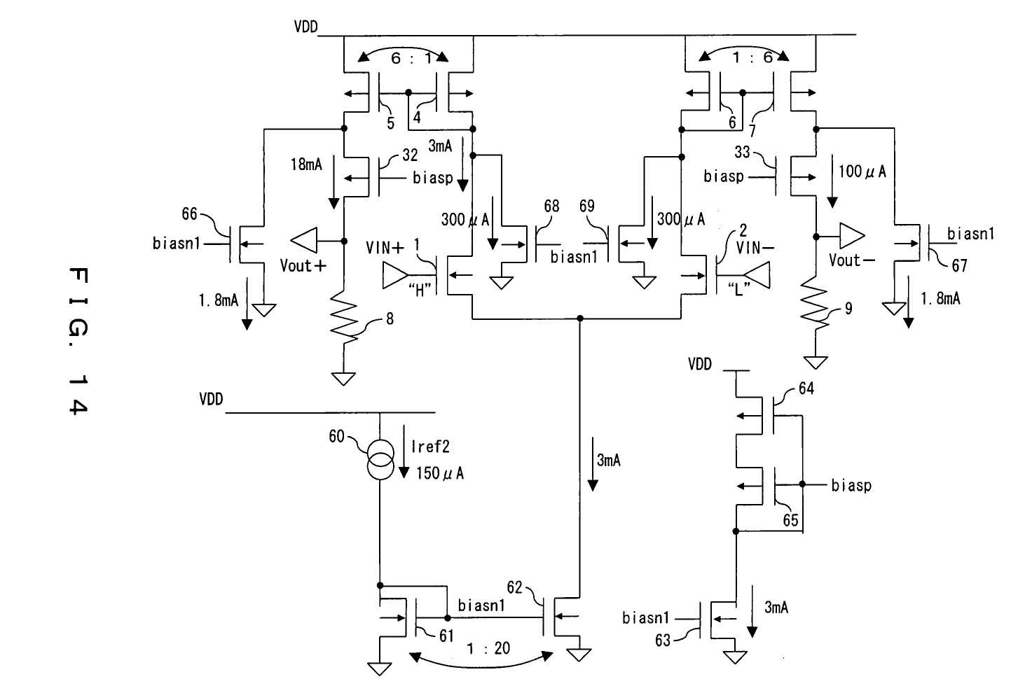

FIG. 14 shows the configuration of the third embodiment of the differential amplifier using the most fundamental current mirror circuit. FIG. 14 is an example of the configuration of a differential amplifier using the fundamental current mirror circuit which comprises a reference current 60 and two transistors 61 and 62. In the third embodiment, four current sources Ia10, Ib11, Ie30 and Id31 comprise transistors 68, 69, 66 and 67 respectively. Bias voltage biasn1 is applied to the gates of these transistors from the gate of the transistor 61. Furthermore this voltage is also applied to the gate of the transistor 63, and the bias voltage biasp which is applied to the gates of two transistors 32 and 33 by the two-stage connection of p-channel transistors 64 and 65 is determined, for example, as shown in FIG. 9.

In the fundamental current mirror circuit used in the third embodiment, the accuracy of the current mirror is a little lower. In particular, when miniaturization processes advance, the inclination of characteristics of the voltage Vds between the drain and the source against the gate current Id in the saturation region becomes large. For example, even if the size ratio of the transistors 61 and 62 is set to 1 to 1, when the value Vds differs between the transistors 61 and 62, it is not possible to make the currents flowing to the transistor 61 and the transistor 62 equal.

The performance of such a current source circuit can be improved by making the output resistance of the current circuit larger. A representative method of making the output resistance larger is a cascade circuit. A current source circuit having a large output resistance can be made by forming the circuit monitoring a reference current and the circuit producing a copy current in a cascade structure, i.e., a structure in which the elements are piled up in a plurality of stages.

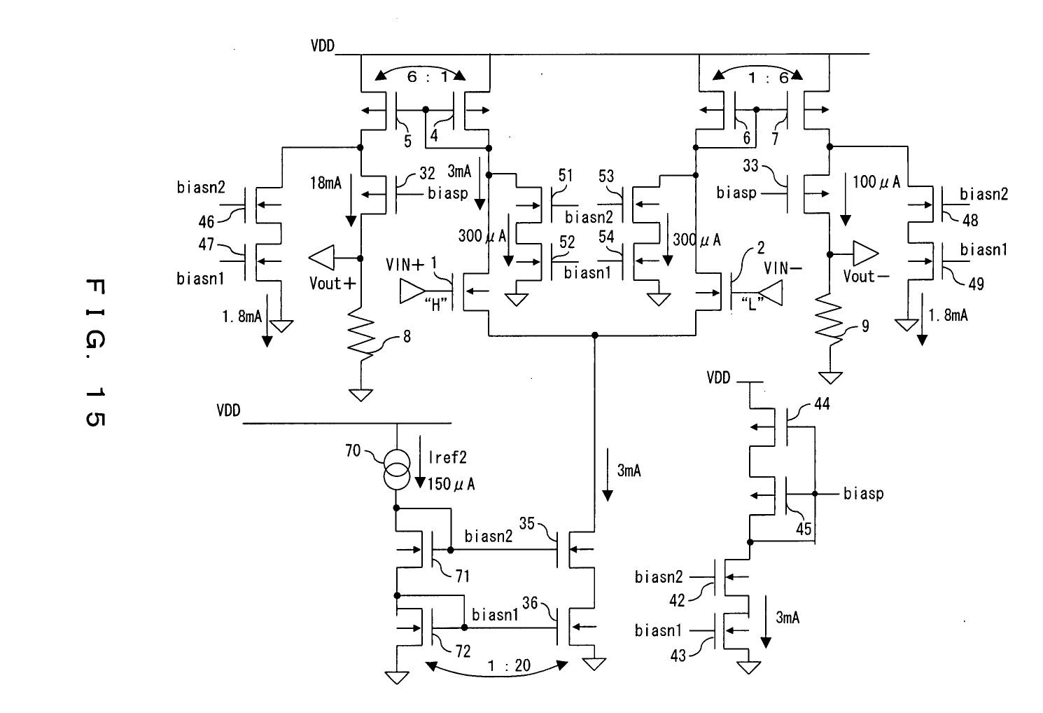

FIG. 15 shows the configuration of the fourth embodiment of the differential amplifier using such a cascade current mirror circuit. In this fourth embodiment, the cascade current mirror comprises a reference current 70, the two-stage transistors 71 and 72 monitoring the reference current, and the two-stage transistors 35 and 36 producing the copy current. The circuit which produces four current sources Ia10, Ib11, Ie30, Id31, and bias voltage biasp is the same circuit as that of the first embodiment shown in FIG. 9, and has the same reference numbers and labels as in FIG. 9.

In the cascade current mirror circuit which is used in the fourth embodiment shown in FIG. 15, there is a problem that the lowest limit value of the output voltage of the current source circuit becomes large. In other words, this current mirror circuit comprises four MOSFETs which operate in the saturation region, and it is necessary to add an overdrive voltage as a further voltage to be applied to the gate to make an electric current flow in addition to the threshold voltage Vr between the gate and the source of the MOSFETs which operate in the region of saturation. In the cascade current mirror circuit, the lowest limit value of the output voltage is the value obtained by adding the value of the threshold voltage and the value of two times the overdrive voltage, and the lowest limit value of the output voltage is about 0.9 V.

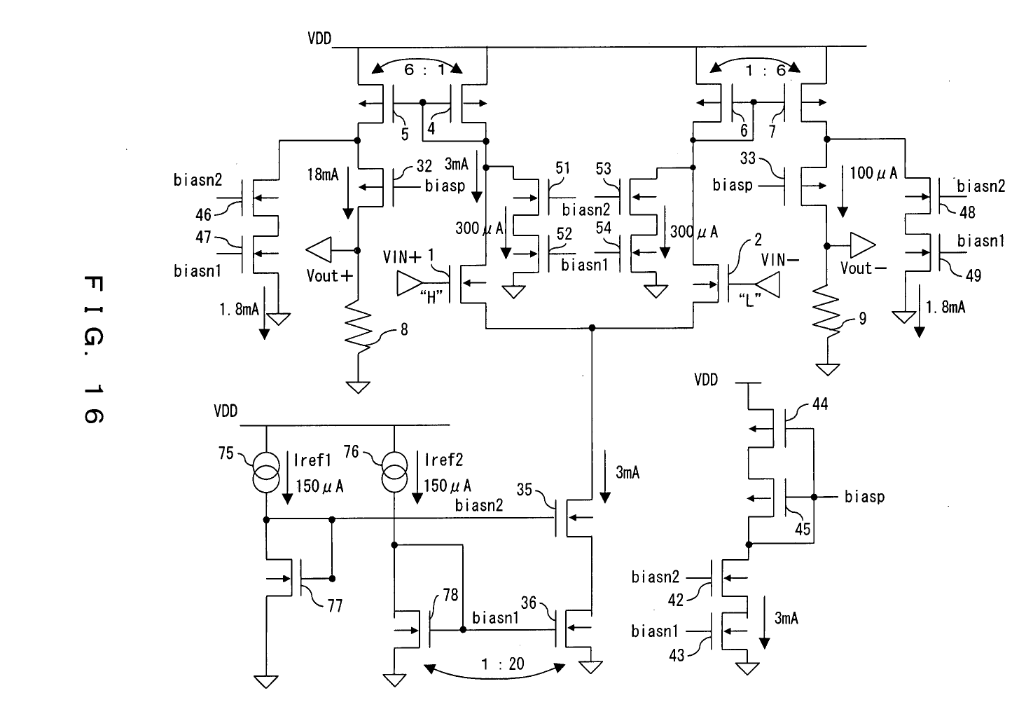

FIG. 16 shows the configuration of the fifth embodiment of the differential amplifier using a transformed cascade current mirror which makes the lowest limit value of the output voltage about two times the overdrive voltage. In FIG. 16, the transformed cascade current mirror circuit comprises two reference currents 75 and 76, two transistors 77 and 78 monitoring these reference currents, and two transistors 35 and 36 producing a copy current. The circuit which produces the other four current sources and the bias voltage biasp is the same as that of the first embodiment shown in FIG. 9, and has the same reference numbers and labels as in FIG. 9, which is the same as that of the fourth embodiment shown in FIG. 15.

In the transformed cascade current mirror circuit used in the fifth embodiment, an error occurs because the circuit in which the reference current Iref2 flows inside the circuit monitoring a current is not cascade-connected. The circuit in which this part is cascade-connected to prevent errors is the low-voltage current mirror circuit used in the first embodiment shown in FIG. 9. In the first embodiment and the second embodiment shown in FIG. 10, the differential amplifier comprises the low-voltage current mirror circuit whose performance is high as a current mirror and which can make the lowest limit of the output voltage lower.

In the third to the fifth embodiments, the first embodiment in which various kinds of current mirror circuits are used for two current sources Ia10 and Ib11 as shown in FIG. 6 is described, but it is possible as a matter of course to use various kinds of current mirror circuits in response to the second embodiment shown in FIG. 10.

Further described below are other embodiments of the present invention. In the third to fifth embodiments, embodiments based on the first embodiment shown in FIG. 9 and the second embodiment shown in FIG. 10 were explained, but in the first embodiment and the second embodiment, there is a problem in that there possibly remains some influence of fluctuations in the manufacturing process of semiconductors.

As explained in FIG. 11, for example, in the first embodiment, during a period when VIN+ is L and transistor 1 is off, it is necessary to make an electric current of 1.8 mA corresponding to 300 μA flowing to the transistor 4 constituting the current mirror circuit flow to the transistors 46 and 47 corresponding to the current source Ie30, but the electric current flowing to the transistor 5 constituting the current mirror circuit becomes 1.8 mA+ΔIds according to the manufacturing process of semiconductors, and this current cannot be sufficiently drawn out by the transistors 46 and 47, so there is a possibility that the current of ΔIds flows out from the output terminal as a leakage current.

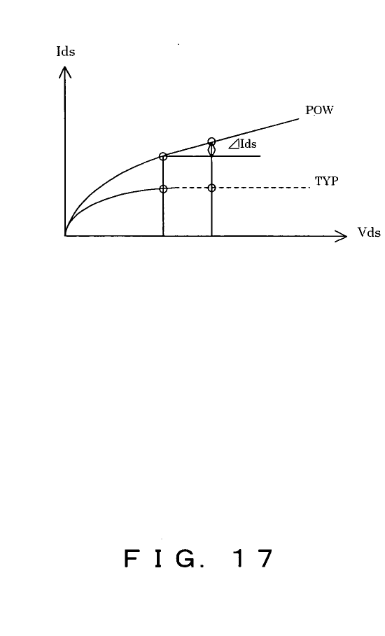

FIG. 17 shows the influence of the conditions for the semiconductor manufacturing process upon the characteristics of the drain source current Ids against the drain source voltage Vds. In FIG. 17, the saturation of the current Ids is remarkable in the typical (TYP) conditions for the manufacturing process, but the current Ids in the power (POW) conditions in which the operation of transistors becomes fast is not so saturated, and even if efforts are made to fix Ids, for example, at 1.8 mA, the current becomes 1.8 mA+ΔIds according to the value of Vds, thus giving rise to a possibility that this current ΔIds flows out from the output terminal as a leakage current.

Next, in the first embodiment shown in FIG. 9, when VIN+becomes H, and the voltages at both ends of the resistor 8 are output as Vout+, first, an electric current flows to the transistors 46 and 47, and the electric potential of the node 3 which is the connecting point of the transistor 5 and the transistor 32 rises, and then the voltage Vds between the drain and source of the transistor 32 is determined according to the electric potential, and finally the electric potential of the output Vout+ is determined. However, there is a problem in that the impedance of the constant current source Ie30 which is constituted by the transistors 46 and 47 is high, and it takes time for the electric potential of the node 3 to be determined, thereby causing jitter of the output voltage Vout+ to be produced. Moreover, since the current of the transistors 46 and 47 varied according to the fluctuations of the manufacturing process, the variation of the jitter also became large according to the fluctuations of the manufacturing process.

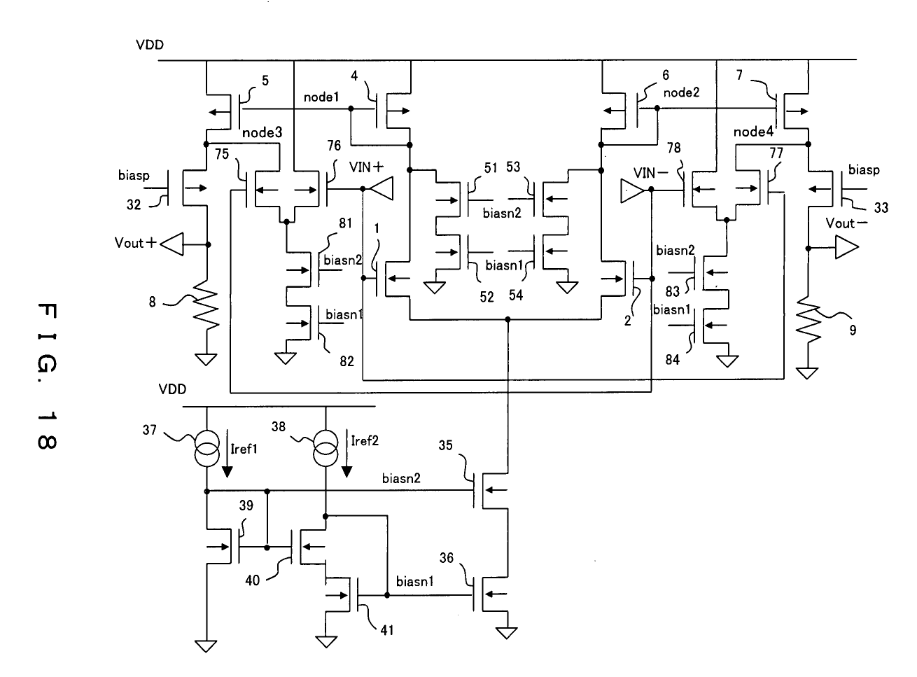

FIG. 18 shows the configuration of the differential amplifier in the sixth embodiment of the present invention. When FIG. 18 is compared with FIG. 9 which shows the first embodiment, it is found to be different in that the current source connected to the node 3 and the node 4 is constituted by two transistors 75 and 76 on the side of the node 3, two transistors 81 and 82 corresponding to the current source, two transistors 77 and 78 on the side of the node 4, and two transistors 83 and 84 corresponding to the current source. The first transistor in claim 6 corresponds to the transistor 5 or 7, the second transistor corresponds to the transistor 32 or 33, the third transistor corresponds to the transistor 75 or 77, and the fourth transistor in claim 7 corresponds to the transistor 76 or 78.

For example, when the input signal VIN+ is L, and VIN− is H on the side of the node 3, the transistor 75 turns on and the transistor 76 turns off. Consequently, when the transistor 1 which constitutes the differential pair is off, the current of 1.8 mA flowing to the transistor 5 flows to the transistors 81 and 82 which constitute the current source via the transistor 75 in response to the current flowing to the transistor 4, for example, of 300 μA. By setting the current of the current source for the two transistors 81 and 82 to a value larger than 1.8 mA, for example, 2 mA, even if the current flowing to the transistor 5 becomes larger than 1.8 mA according to the fluctuations of the manufacturing process, said current can be absorbed by the current of the current source constituted by the transistors 81 and 82 without making the leakage current ΔIds flow to the transistor 32.

Bias voltages, biasn2 and biasn1, are supposed to be applied to the transistors 81 and 82 in the same way as for the transistors 46 and 47 shown in FIG. 9, and this is based on the premise that the current of the current source is set to a value different from 1.8 mA, for example, 2 mA according to the size of the transistor, but it is possible as a matter of course to apply, for example, to the transistor 82 the voltage of biasn3 which differs from a bias voltage for the transistor 47 and set the current of the current source to 2 mA.

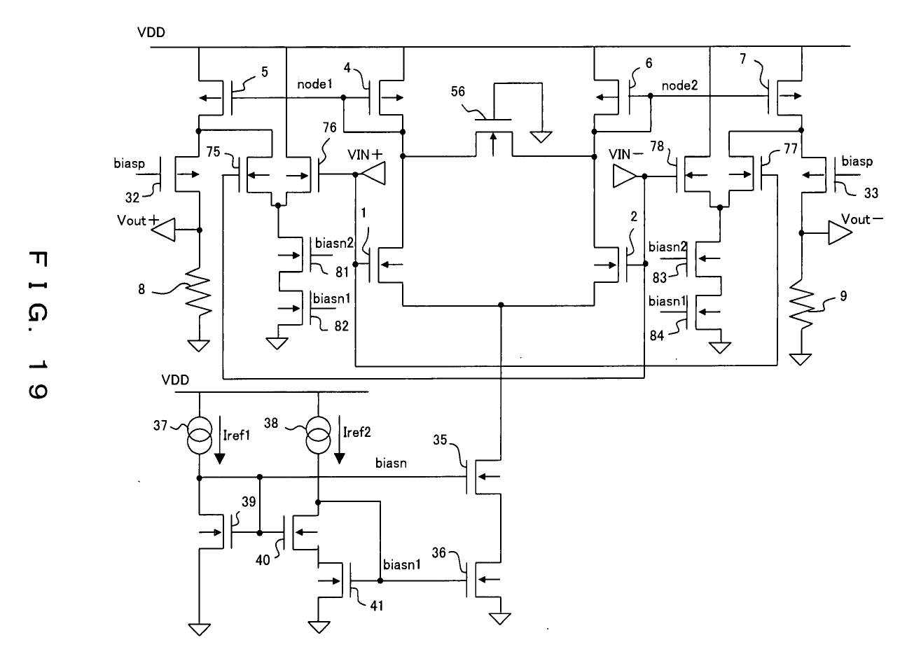

FIG. 19 shows the configuration of the seventh embodiment of the differential amplifier. FIG. 19 is a drawing in which the current source connected to the node 3 and the current source connected to the node 4 have been changed in the same way as in FIG. 18 in response to the second embodiment shown in FIG. 10, and since the operation of this embodiment is basically the same as that of the sixth embodiment shown in FIG. 18, detailed descriptions of said operation are omitted.

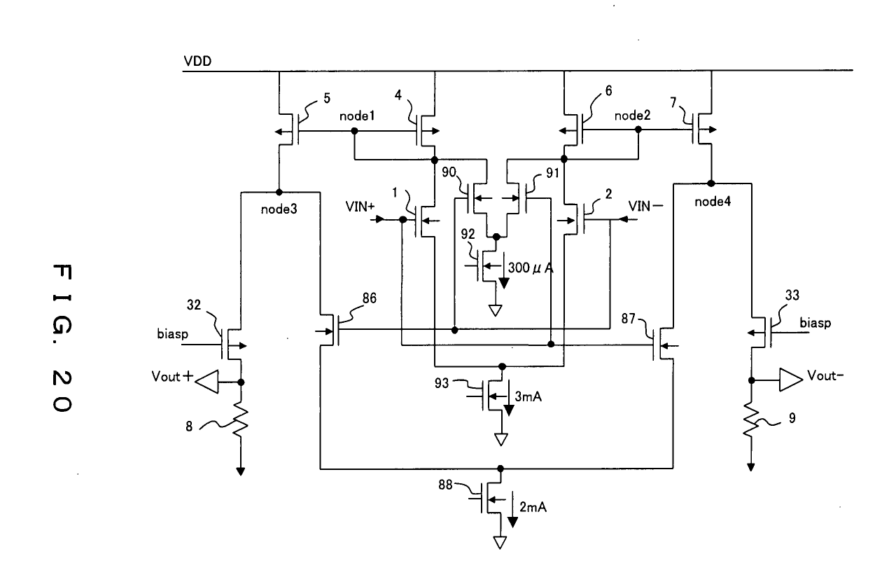

FIG. 20 shows the configuration of the eighth embodiment of the differential amplifier of the present invention. Like the sixth and seventh embodiments, in this eighth embodiment, a leakage current from the output terminal due to the fluctuations of the manufacturing process and the variation of the jitter can be prevented, and the increase of power consumption on the grounds that a current of, for example, 300 μA is always flowing to two current sources Ia10 and Ib11 in the basic configuration shown in FIG. 6 can be prevented.

Two current sources Ie30 and Id31 shown in FIG. 6 comprise the transistor 86 connected to the node 3 in FIG. 20, the transistor 87 connected to the node 4, and the transistor 88 as the current source to which these two transistors are connected. When VIN− is H, and VIN+ is L on the side of the node 3, the transistor 86 turns on, and even if the current flowing through the transistor 5 increases above 1.8 mA due to the fluctuations of the manufacturing process, the increase is absorbed by 2 mA flowing to the transistor 88, and a leakage current is prevented from flowing out from the output terminal. At that time, on the side of the node 4, the voltages at both ends of the resistor 9 are output as Vout−, but since the transistor 87 is off, the current flowing to the current source constituted by the transistor 88 does not affect the output current according to the output voltage Vout−. The first transistor in claim 9 corresponds to the transistor 5 or 7, the second transistor corresponds to the transistor 32 or 33, and the third and fourth transistors correspond to the transistors 86 and 87.

The transistors 90 and 91 shown in FIG. 20 and the transistor 92 constituting the current source of 300 μA correspond to two current sources Ia10 and Ib11 shown in FIG. 6. However, the actual current source is only one transistor 92.

When the input signal VIN+ is H, and VIN− is L in FIG. 20, the transistor 90 turns off and the transistor 91 turns on, and the current of 300 μA which should flow to the transistor 6 flows via the transistor 91. On the other hand, when VIN+ is L, and VIN− is H, the transistor 90 turns on, and the transistor 91 turns off, and the current of 300 μA which should flow to the transistor 4 flows via the transistor 90. As a result, the transistor 92 alone is sufficient for the current source, thus causing the power consumption to be reduced. It has been found that the current consumption of about 2.1 mA can be reduced when seeing the current consumption on the side of the power source.

In the sixth to eighth embodiments, it is possible to prevent a leakage current of the output occurring due to the fluctuations of the manufacturing process, and lessen the variation of the jitter, as well as to realize low power consumption in the eighth embodiment. It is also possible as a matter of course to use various kinds of current mirror circuits similar to those in the first to fifth embodiments for transistor 93, etc. constituting the current source of 3 mA in FIG. 20.

Moreover, for example, in the sixth embodiment shown in FIG. 18, it is also possible as a matter of course to use the transistors 90 to 92 corresponding to one current source instead of using the transistors 51 to 54 corresponding to two current sources, and to employ a combination of various embodiments, for example, by changing the configuration using the transistors 75 to 78, and 81 to 84 into the configuration using the transistors 86 to 88.

1. A differential amplifier, comprising:
a first and second transistor to which the inputs to the differential amplifier are respectively provided and
first and second current sources each connected between a ground and each terminal of said first and second transistors which provides the output point of said differential amplifier.

2. The differential amplifier according to claim 1, further comprising:
first and second current mirror circuits each of which comprises third and fourth transistors and delivers the output of the differential amplifier to the side of a load by means of an electric current,
said third transistor being connected to one of said first and second transistors and to which a monitor current flows in the current mirror circuit, and
said fourth transistor to which a copy current flows in the current mirror circuit,
a fifth transistor being connected between said fourth transistor and a resistor as the load, and to which the output of the differential amplifier is delivered,
fifth transistor turning off when one of the inputs of said first and second transistors is supplied “L”, and
a third current source connected between the ground and the connection point of the fourth transistor and the fifth transistor.

3. The differential amplifier according to claim 2, wherein
said first, second and third current sources comprise sixth transistors respectively; and
the sixth transistors and a first bias circuit unit which applies a bias voltage to the sixth transistors, constituting third current mirror circuits.

4. The differential amplifier according to claim 3, further comprising:
a second bias circuit for applying a second bias voltage to the fifth transistor, said second bias circuit comprising at least one stage of a seventh transistor for receiving a first bias voltage from a first bias circuit and two-stage eighth transistors connected between the power source and the seventh transistor for applying a second bias voltage to the fifth transistor so that the fifth transistor turns off when “L” is applied to one of the inputs of the differential amplifier.

5 The differential amplifier according to claim 4, wherein
the gate of the two-stage eighth transistors is connected to the connection point of the seventh transistor of one or more stages and the two-stage eighth transistor; and
the second bias voltage which is supplied to the fifth transistor is determined by adjusting the size of the two-stage eighth transistors and the current which flows to the eighth transistor.

6. The differential amplifier according to claim 3, wherein
the current mirror circuits is a cascade current mirror circuit in which the output impedance of the current source is large.

7. The differential amplifier according to claim 3, wherein
the current mirror circuit is a transformed cascade current mirror circuit in which the lowest limit of the output voltage of the current source is low.

8. The differential amplifier according to claim 3, wherein
the current mirror circuit is a low-voltage mirror circuit which cascade-connects the fourth transistor to which a copy current flows and the third transistor to which a monitor current flows.

9. The differential amplifier according to claim 1, further comprising:
a current mirror circuit which delivers the output of the differential amplifier to the side of a load by means of an electric current,
a first transistor to which one of the inputs is supplied, and which is connected to the transistor to which a monitor current flows in the current mirror circuit, and to which a copy current flows in the current mirror circuit;
a second transistor which is connected to the resistor as a load to which the output of the differential amplifier is delivered, and which turns off when the input to the transistor to which one of two inputs is supplied is L;
a third transistor which is connected to the connecting point of the first transistor and second transistor and which turns on when the input to the transistor to which one of the two inputs is given is L; and
a current source connected between the third transistor and the grounding wire.

10. The differential amplifier according to claim 9, further comprising:
a fourth transistor which is connected between the source voltage and the current source connected between the third transistor and the grounding wire, and which turns on when the input to the transistor to which one of the inputs is given is H.

11. A differential amplifier, comprising:
a first and second transistor to which the inputs to the differential amplifier are respectively provided and
a circuit element connected between the terminals of said first and second transistors which provide the output point of said differential amplifier.

12. The differential amplifier according to claim 11, wherein
the circuit element comprises a transistor which makes a weak current flow, or a resistor.

13. The differential amplifier according to claim 11, further comprising:
first and second current mirror circuits each of which comprises third and fourth transistors and delivers the output of the differential amplifier to the side of a load by means of an electric current,
said third transistor being connected to one of said first and second transistors and to which a monitor current flows in the current mirror circuit, and
said fourth transistor to which a copy current flows in the current mirror circuit,
a fifth transistor being connected between said fourth transistor and a resistor as the load, and to which the output of the differential amplifier is delivered,
fifth transistor turning off when one of the inputs of said first and second transistors is given, and
a current source connected between the ground and the connection point of the fourth transistor and the fifth transistor.

14. The differential amplifier according to claim 13, wherein
said current source comprises sixth transistors; and
the sixth transistors and a first bias circuit unit which applies a bias voltage to the sixth transistors, and constituting third current mirror circuits respectively.

15. The differential amplifier according to claim 14, further comprising:
a second bias circuit for applying a second bias voltage to the fifth transistor, said second bias circuit comprising at least one stage of a seventh transistor for receiving a first bias voltage of a first bias circuit and two-stage eighth transistors connected between the power source and the seventh transistor for applying a second bias voltage to the fifth transistor so that the fifth transistor turns off when “L” is applied to the circuit of the differential amplifier.

16. The differential amplifier according to claim 15, wherein
the gate of the two-stage eighth transistors is connected to the connection point of the seventh transistor of one or more stages and the two-stage eighth transistors; and
the second bias voltage which is supplied to the fifth transistor is determined by adjusting the size of the two-stage eighth transistors and the current which flows to the eighth transistor.

17. The differential amplifier according to claim 14, wherein
the current mirror circuits is a cascade current mirror circuit in which the output resistance of the current source is large.

18. The differential amplifier according to claim 14, wherein
the current mirror circuit is a transformed cascade current mirror circuit in which the lowest limit of the output voltage of the current source is low.

19. The differential amplifier according to claim 14, wherein
the current mirror circuit is a low-voltage mirror circuit which cascade-connects the fourth transistor to which a copy current flows and the third transistor to which a monitor current flows.

20. The differential amplifier according to claim 11, further comprising:
a current mirror circuit which delivers the output of the differential amplifier to the side of a load by means of an electric current;
a first transistor to which one of the inputs is given, and which is connected to the transistor to which a monitor current flows in the current mirror circuit, and to which a copy current flows in the current mirror circuit;
a second transistor which is connected to the resistor as a load to which the output of the differential amplifier is delivered, and which turns off when the input to the transistor to which one of two inputs is given is L;
a third transistor which is connected to the connecting point of the first transistor and second transistor and which turns on when the input to the transistor to which one of the two inputs is given is L; and
a current source connected between the third transistor and the grounding wire.

21. The differential amplifier according to claim 20, further comprising:
a fourth transistor which is connected between the source voltage and the current source connected between the third transistor and the grounding wire, and which turns on when the input to the transistor to which one of the two inputs is given is H.

22. A differential amplifier, comprising:
two transistors which constitute the differential amplifier and which are connected to each terminal which can be the output point for the differential amplifier among the terminals of each transistor to which one of the two inputs for the differential amplifier is given, and one of which turns off when the other is on, and one of which turns on when the other is off; and
the current source connected between the two transistors and the grounding wires.

23. The differential amplifier according to claim 22, further comprising:
a current mirror circuit which delivers two outputs of the differential amplifier to the side of a load by means of an electric current;
a first transistor to which one of the inputs is given, and which is connected to the transistor to which a monitor current flows in the current mirror circuit, and to which a copy current flows in the current mirror circuit;
a second transistor which is connected to the resistor as a load to which the output of the differential amplifier is delivered, and which turns off when the input to the transistor to which one of the two inputs is given is L;
third and fourth transistors which are connected to the connecting point of the first transistor and the second transistor, and one of which turns off when the other is on, and one of which turns on when the other is off; and
a current source connected between the third and fourth transistors and the grounding wires.

24. A differential amplifier, comprising:
a transistor which constitutes the differential amplifier and to which one of two inputs to the differential amplifier is given; and
a cut-off prevention device which is connected to the connecting point of the transistor to which a monitor current of the current mirror circuit flows to deliver the output of the differential amplifier to the side of the load and which makes the current flow which does not cut off the transistor to which the monitor current flows even when the input to the transistor to which the input is given is L.
